(19) United States
(12) Patent Application Publication
(10) Pub. No.: US 2003/0124795 A1
(43) Pub. Date: Jul. 3, 2003

(54) Method of forming a polysilicon to polysilicon capacitor

(76) Inventor: Shyh-Dar Lee, Hsinchu Hsien (TW)

Correspondence Address: Merchant & Gould, P O Box 2903, Minneapolis, MN, 55402-0903, US

(21) Appl. No.: 10/155,555

(22) Filed: May 24, 2002

(30) Foreign Application Priority Data
Dec. 31, 2001 (TW) 90133412

(51) Int. Cl. H01L 21/8234; H01L 21/20

(52) U.S. Cl. 438/253; 438/250; 438/393

(57) ABSTRACT

A method of forming a polysilicon to polysilicon capacitor on a substrate, wherein the substrate has an insulating area and an active area and is covered by a first insulating layer. First, a first conductive layer, a second insulating layer and a second conductive layer are formed on the first insulating layer in sequence. Next, the second conductive layer and the second insulating layer are etched in sequence to form a top plate and a dielectric layer on the first conductive layer. Finally, the first conductive layer and the first insulating layer are etched to form a bottom plate over the insulating area and a gate structure over the active area.

### BACKGROUND OF THE INVENTION

1. Field of the Invention

The present invention relates to fabrication of a semiconductor device. In particular, the present invention relates to a method of forming a polysilicon to polysilicon capacitor, the application of which simplifies the steps of the double level polysilicon process (DLP), thereby reducing manufacturing cost.

2. Description of the Related Art

CMOS and BiCMOS are rapidly evolving as the premiere technology for integrating highly complex analog-digital subsystems on a single chip. Such single chip subsystems require precision capacitors. Polysilicon to polysilicon capacitors have been increasingly used to provide this necessary precision.

In prior art devices, several DLP processes have often been developed to form the polysilicon to polysilicon capacitors. In particular, the LinEPIC DLP process uses a two-mask approach to define a capacitor bottom plate. Initially, the first mask was used to etch a frame around the bottom plate without removing the polysilicon diffusion area. A sidewall oxide deposition and etch followed to form a slope surface at the edge of the bottom plate. The purpose of the sidewall oxide was to help prevent polysilicon filament formation when the top plate was defined. After the interlevel dielectric was formed, a second mask was used to protect the bottom plate, while allowing the interlevel and first polysilicon to be removed from all other areas. The second polysilicon deposition, patterning, and etching formed the capacitor top plate and CMOS gates. While this approach helped eliminate polysilicon filament, it is considerably complicated and expensive. Additionally, the DLP process requires planarization of the entire surface prior to metallization the contacts because of topography problems.

### SUMMARY OF THE INVENTION

An object of the present invention is to provide a method of forming a polysilicon to polysilicon capacitor to reduce manufacturing cost and simplify the process steps.

Another object of the present invention is to provide a method of forming a polysilicon to polysilicon capacitor in which no additional step of planarization prior to depositing metal on the appropriate contact points is required.

In accordance with the objects of this invention, a novel method of forming a polysilicon to polysilicon capacitor on a substrate is disclosed, wherein the substrate has an insulating area and an active area and is covered by a first insulating layer. The method of the present invention comprises the steps of: forming a first conductive layer, a second insulating layer and a second conductive layer on the first insulating layer in sequence; etching the second conductive layer and the second insulating layer in sequence to form a top plate and a dielectric layer on the first conductive layer; and etching the first conductive layer and the first insulating layer to form a bottom plate over the insulating area and a gate structure over the active area.

### BRIEF DESCRIPTION OF THE DRAWINGS

The present invention can be more fully understood by reading the subsequent detailed description in conjunction with the examples and references made to the accompanying drawings, wherein:

FIGS. 1 to 4 are section diagrams showing a method of forming a polysilicon to polysilicon capacitor according to the present invention.

### DETAILED DESCRIPTION OF THE PREFERRED EMBODIMENT

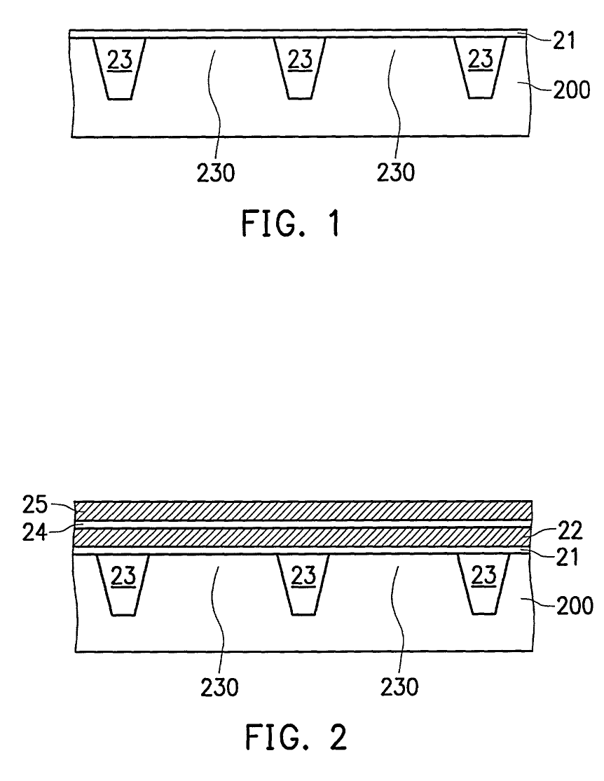

FIGS. 1 to 4 show a method of forming a polysilicon to polysilicon capacitor on a substrate according to the present invention.

In FIG. 1, a semiconductor substrate 200 (i.e. silicon substrate) having an insulating area 23 such as a shallow trench isolation (STI) area and an active area 230 thereon is provided. A first insulating layer 21 such as an oxide layer is then formed on the substrate 200. Since the first insulating layer 21 on the active area 230 serves as a gate oxide layer, it is usually formed by thermal oxidation at high temperature such as 900° C., and its thickness is about 100 angstroms (Å).

In FIG. 2, a first conductive layer 22, a second insulating layer 24 and a second conductive layer 25 are formed in sequence on the first insulating layer 21 in sequence by low-pressure chemical vapor deposition (LPCVD) using single wafer technique. For example, the first and second conductive layers 22 and 25 are polysilicon layers with thickness about 1500 to 2500 Å and 800 to 1500 Å, respectively, formed by LPCVD using silane (SiH₄) as reactant. A phosphorous dopant may be used in order to make the layers 22 and 25 having conductivity. For example, a phosphorus oxychloride (POCl₃) dopant is diffused into the layers 22 and 25, ion implantation is performed in the layers 22 and 25 using arsenic (AS) or phosphorus (P), or an LPCVD is performed in the layers 22 and 25 using SiH₄ or phosphine (PH₃) to form n-type doped polysilicon layers. The second insulating layer 24 with a thickness about 100 to 400 Å is SiO₂, SiN, NO-doped SiO₂, TiO₂, ZnO₂, Ta₂O₅ or HfO₂ formed by LPCVD using single wafer technique.

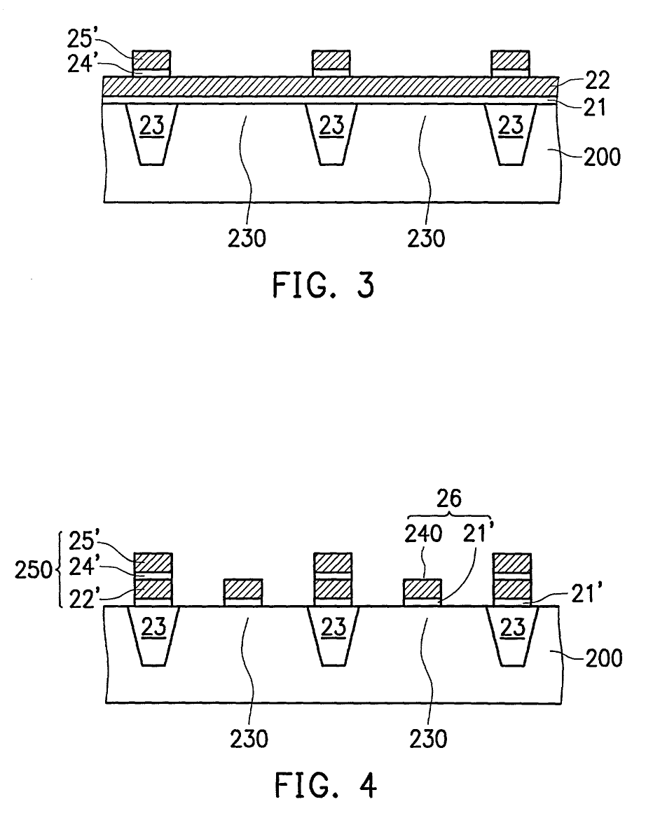

In FIG. 3, a patterned resist layer (not shown) is formed on the second conductive layer 25 to define a top plate and a dielectric layer of a capacitor structure (not shown) by lithography. Subsequently, anisotropic etching such as reactive ion etching (RIE) is performed to etch the second conductive layer 25 and the second insulating layer 24 on the first conductive layer 22 in sequence using the resist layer as a mask. The dielectric layer 24′ and the top plate 25′ of the capacitor structure are formed, and the patterned resist layer is then stripped.

In FIG. 4, the first conductive layer 22 and the first insulating layer 21 on the substrate 200 are patterned by lithography and etching to form a bottom plate 22′ of a capacitor structure 250 over the insulating area 23 and a gate structure 26 over the active area 230. The gate structure 26 is composed of a gate oxide layer 21′ and a gate polysilicon layer 240.

In this embodiment, since the second insulating layer 24 is as an etch stop layer to protect the underlying polysilicon layer 22 and serves as a dielectric layer of a capacitor, the process steps are simplified and the cost is reduced. Moreover, the underlying polysilicon layer 22 is not corroded to prevent the polysilicon filament formation during the top plate 25′ of the capacitor structure 250 is formed.

Compared with the conventional method of forming a DLP capacitor, the present invention has the advantages of:

(1) Since the method of the present invention uses only one mask to define the dielectric layer 24′ and top plate 25′ of the capacitor structure 250, the process steps are simplified and the cost is reduced.

(2) Since the method of the present invention reduces number of the masks and etching steps to prevent the topography problems, no additional step of planarization prior to depositing metal on the appropriate contact points is required.

Finally, while the invention has been described by way of example and in terms of the preferred embodiment, it is to be understood that the invention is not limited to the disclosed embodiment. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of forming a polysilicon to polysilicon capacitor on a substrate, wherein the substrate has an insulating area and an active area and is covered by a first insulating layer has, comprising steps of:
forming a first conductive layer, a second insulating layer and a second conductive layer on the first insulating layer in sequence;
etching the second conductive layer and the second insulating layer in sequence to form a top plate and a dielectric layer on the first conductive layer; and
etching the first conductive layer and the first insulating layer to form a bottom plate over the insulating area and a gate structure over the active area.

2. The method as claimed in claim 1, wherein the substrate is a silicon substrate.

3. The method as claimed in claim 1, wherein the first insulating layer is an oxide layer.

4. The method as claimed in claim 1, wherein the first conductive layer, the second conductive layer and the first insulating layer are formed by low-pressure chemical vapor deposition using single wafer technique.

5. The method as claimed in claim 1, wherein the first and second conductive layers are n-type doped polysilicon layers.

6. The method as claimed in claim 1, wherein the second insulating layer is SiO₂, SiN, NO-doped SiO₂, TiO₂, ZnO₂, Ta₂O₅, or HfO₂.

7. The method as claimed in claim 1, wherein the second insulating layer is used as an etch stop layer for the first conductive layer.

8. The method as claimed in claim 1, wherein the gate structure is composed of a gate oxide layer and a gate polysilicon layer.

9. The method as claimed in claim 1, wherein the insulating area is a shallow trench isolation area.
